(19) United States
(12) Patent Application Publication
(10) Pub. No.: US 2025/0093435 A1
(43) Pub. Date: Mar. 20, 2025

(54) MAGNETIC FIELD GRADIOMETER

(71) Applicant: Q.ant GmbH, Stuttgart (DE)

(72) Inventors: Ferdinand Schiller, Korntal-Münchingen (DE); Robert Rölver, Calw (DE); Katharina Jag-Lauber, Winterbach (DE)

(21) Appl. No.: 18/963,591

(22) Filed: Nov. 28, 2024

Related U.S. Application Data
(63) Continuation of application No. PCT/EP2023/063408, filed on May 17, 2023.

(30) Foreign Application Priority Data
May 31, 2022 (DE) 10 2022 205 468.7

(51) Int. Cl. G01R 33/26; G01R 33/36

(52) U.S. Cl. CPC G01R 33/26; G01R 33/36

(57) ABSTRACT

A magnetic field gradiometer includes two spatially spaced-apart measurement regions including color centers in a diamond, which emit fluorescence upon excitation by an excitation light, a first detector for detecting the fluorescence from a first measurement region, a second detector for detecting the fluorescence from a second measurement region, a first microwave emitter for applying a first microwave field to the first measurement region, a second microwave emitter for applying a second microwave field to the second measurement region, an evaluation device configured to determine a magnetic field gradient based on the detected fluorescence from the first and the second measurement regions, and a signal generator unit configured to generate a first and a second microwave signals for the first and the second microwave emitters, respectively. Each of the first and the second microwave signals includes two frequency components with a phase offset of π with respect to one another.

### CROSS REFERENCE TO RELATED APPLICATIONS

This application is a continuation of International Application No. PCT/EP2023/063408 (WO 2023/232490 A1), filed on May 17, 2023, and claims benefit to German Patent Application No. DE 10 2022 205 468.7, filed on May 31, 2022. The aforementioned applications are hereby incorporated by reference herein.

### FIELD

Embodiments of the present invention relate to a magnetic field gradiometer for determining a magnetic field gradient.

### BACKGROUND

Highly sensitive magnetometers can be used, inter alia, to record magnetic signals of brain or nerve activity with local resolution in order thus to use novel human-machine interfaces for the control of prostheses, exoskeletons or machines. Since the amplitude of the used signal of human nerve activity might be below that of ambient magnetic noise, solutions are needed for the suppression of ambient noise in the above-described applications. One such solution lies in the use of gradiometric sensor concepts, in which the measurement region of a first magnetometer is placed directly on the magnetic field source and the measurement region of a second magnetometer is arranged at a defined distance from the first measurement region of the magnetic field source. In this setup, the magnetometer with the second measurement region at the greater distance only records ambient noise while the measurement region of the magnetometer arranged closer to the signal source detects the used signal in addition to the ambient noise. A signal which only still contains the used signal and which is referred to as magnetic field gradient within this application is obtained by subtracting the noise signal recorded by the first magnetometer from the signal of the second magnetometer. In comparison with the magnetic field measurement by means of a single magnetometer, a magnetic field gradiometer allows elimination or suppression of the ambient noise which has the same effect on both magnetometers.

Some magnetic field gradiometers are based on a magnetic field-dependent change of the fluorescence of color centers, typically of NV centers, in a diamond in the presence of an alternating magnetic field. More precisely, this involves optical detection of magnetic resonance (ODMR). The principles of such a detection are described in the article “Nanoscale imaging magnetometry with diamond spins under ambient conditions” by G. Balasubramian et al., Nature 455, 648 (2008). This principle will be explained hereinafter on the basis of the example of an NV center.

An NV center is a special color center in a diamond crystal lattice which consists of a nitrogen atom and an adjacent defect. More precisely, an NV center is understood in the scope of this application as a negatively charged NV center. The magnetic field gradiometers are furthermore designed for measuring at a multiplicity of NV centers (so-called ensemble magnetometry).

The energy levels of an NV center comprise a ground state and an excited state in the form of a triplet in each case. The respective three states of each triplet differ in their magnetic spin quantum number, mₛ=−1,0, +1. The mₛ=±1 states are higher energy due to the spin-spin interaction than the mₛ=0 state. Without magnetic field, the mₛ=±1 states are degenerate (if the hyperfine structure is neglected), thus have the same energy. In the presence of a magnetic field, in contrast, the degeneracy of the mₛ=±1 states is lifted proportionally to the magnetic field due to the Zeeman effect.

The NV centers can be pumped out of the ground state into the excited state by radiating in excitation light in the green wavelength range. The return into the ground state partially takes place with the emission of red fluorescence. The intensity of this fluorescence is dependent on the population distribution between the mₛ=−1,0, +1 states of the triplet ground state. This population distribution can be influenced by interaction with a resonant microwave field. More precisely, in a microwave field having the frequencies f₊ and f₋, corresponding to the transitions between the mₛ=0 and the mₛ=+1 state or the mₛ=−1 state, a drop of the detected intensity of the fluorescence occurs.

The frequency of the microwave field is now varied to determine a magnetic field by means of a corresponding magnetometer. Depending on the frequency of the microwave field, the measured intensity of the fluorescence has minima, also called a “dip” or “dips”, at the frequencies f_{±}. The magnetic field is determined via the location of these minima.

The frequencies f₊ and f₋ result here from the formula

$${f}_{\pm } = D ( T , p ) \pm {γ}_{NV} {B}_{0} ,$$

see, for example, the article “Integrated and portable magnetometer based on nitrogen-vacancy ensembles in diamond” by F. Stürner et al., arXiv: 2012.01053. In this case, D(T, p) is the split between the mₛ=0 state and the mₛ=±1 states of the triplet ground state which is dependent on the temperature T and the ambient pressure p, γ_{NV} is the gyromagnetic ratio of the NV center, and B₀ is the projection of the magnetic field on the corresponding axis of the NV center.

In the case of a magnetic field gradiometer, such measurements are taken in two spatially spaced-apart measurement regions, in each of which NV centers or other diamond color centers are arranged. The magnetic field gradient is then determined from a comparison of the minima of the fluorescence from the first and the second measurement regions and the spacing between the measurement regions (see above).

However, a temperature difference and/or a pressure difference can easily arise between the two magnetometers or the two measurement regions due to the design of such magnetic field gradiometers. Such a temperature difference and/or pressure difference can distort the ascertained magnetic field gradients on account of the temperature- and pressure dependence of the frequencies f_{±}.

A magnetometer employing a double resonance technique for compensating the effect of a thermal shift of the energy levels of the NV centers is described in the article “Diamond magnetometer enhanced by ferrite flux concentrators” by I. Fescenko et al., Physical Review Research 2, 023394 (2020). To this end, two frequency-modulated microwave signals containing two frequency components with a phase offset of π with respect to one another are combined and radiated on the diamond crystal having the NV centers using a microwave emitter. The fluorescence of the NV centers is detected using a photodetector, supplied to a lock-in amplifier and demodulated at the latter with the aid of a reference signal. An output signal of the lock-in amplifier is generated in this way; it is proportional to the difference (f₊-f₋) between the two frequencies f₊ and f₋ and not dependent on the thermal shift.

The article “Robust high-dynamic-range vector magnetometry with nitrogen-vacancy centers in diamond”, H. Clevenson et al., Appl. Phys. Lett. 112, 252406 (2018), describes a magnetometer having a large dynamic range. To realize the large dynamic range, closed-loop control of the carrier frequency of a microwave signal with the aid of the feedback of a lock-in signal is proposed.

The article “Diamond Magnetometry and Gradiometry Towards Subpicotesla de Field Measurement”, Chen Zhang et al., Phys. Rev. Applied 15, 064075 (2021), describes a magnetometer and a gradiometer in which, inter alia, a continuous wave (cw) ODMR measurement is performed in combination with a lock-in detection, in which the two microwave frequencies of the NV centers are excited simultaneously.

### SUMMARY

Embodiments of the present invention provide a magnetic field gradiometer for determining a magnetic field gradient. The magnetic field gradiometer includes at least one excitation light source for emitting excitation light, and two spatially spaced-apart measurement regions for magnetic field measurement. The two measurement regions include color centers in a diamond, which emit fluorescence upon excitation by the excitation light. The magnetic field gradiometer further includes a first detector for detecting the fluorescence from the first measurement region, a second detector for detecting the fluorescence from the second measurement region, a first microwave emitter for applying a first microwave field to the first measurement region, a second microwave emitter for applying a second microwave field to the second measurement region, an evaluation device configured to determine the magnetic field gradient based on the detected fluorescence from the first measurement region and the detected fluorescence from the second measurement region, and a signal generator unit configured to generate a first microwave signal for the first microwave emitter and a second microwave signal for the second microwave emitter. The first microwave signal includes at least two frequency components with a phase offset of π with respect to one another. The second microwave signal includes at least two frequency components with a phase offset of π with respect to one another.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a schematic illustration of the energy levels of an NV center in a diamond crystal and the dependence of the energy levels on magnetic field strength, temperature and pressure;

FIG. 2a and FIG. 2b show schematic illustrations of a magnetic resonance excited with the aid of a frequency-modulated microwave signal, and a magnetic resonance signal that was demodulated by means of a lock-in amplifier, according to some embodiments;

FIG. 3 shows a schematic illustration of an exemplary embodiment of a magnetic field gradiometer having two frequency mixers for forming a respective microwave signal with two frequency components with a phase offset of π with respect to one another, the frequency components being emitted by way of a respective microwave emitter in order to apply a microwave field to a first and a second measurement region;

FIG. 4 shows a schematic illustration of the frequency components of a microwave signal of the magnetic field gradiometer from FIG. 3, according to some embodiments;

FIG. 5 shows schematic illustrations of demodulated single and double resonance signals and their dependence on resonance shifts that can be traced back to changes in the magnetic field and in the temperature, according to some embodiments;

FIG. 6 shows a schematic illustration of an exemplary embodiment of a magnetic field gradiometer having two power adders for adding two respective frequency-modulated microwave signals to form a first and a second microwave signal, respectively;

FIG. 7 shows a schematic illustration of the frequency components of a microwave signal of the magnetic field gradiometer from FIG. 6, according to some embodiments; and

FIG. 8 shows a schematic illustration of an exemplary embodiment of a magnetic field gradiometer which has a respective pair of demodulators for evaluating the fluorescence from the first and the second measurement region.

### DETAILED DESCRIPTION

Embodiments of the invention provide a magnetic field gradiometer that is able to effectively compensate external interference, in particular the influence of temperature and/or pressure.

According to a first aspect, a magnetic field gradiometer includes at least one excitation light source for emitting excitation light, two spatially spaced-apart measurement regions for magnetic field measurement, comprising color centers in a diamond, preferably NV centers, which emit fluorescence upon excitation by the excitation light, a first detector for detecting the fluorescence from the first measurement region, a second detector for detecting the fluorescence from the second measurement region, a first microwave emitter for applying a first microwave field to the first measurement region, a second microwave emitter for applying a second microwave field to the second measurement region, and an evaluation device designed to determine the magnetic field gradient on the basis of the detected fluorescence from the first measurement region and on the basis of the detected fluorescence from the second measurement region. The magnetic field gradiometer further includes a signal generator unit designed to generate a first microwave signal for the first microwave emitter, the said first microwave signal containing at least two frequency components with a phase offset of π with respect to one another, and a second microwave signal for the second microwave emitter, the said second microwave signal containing at least two frequency components with a phase offset of π with respect to one another.

According to some embodiments, a microwave signal containing (at least) two frequency components with a phase offset of π with respect to one another is generated for each measurement region or for each one of the two magnetometers. The phase offset or the relative modulation phase of π or 180° between the two frequency components leads to a reflection of the demodulated individual resonance signals with respect to the vertical axis during demodulation, e.g. with the aid of a lock-in amplifier (see below). A change in the magnetic field leads to a shift of the frequencies of the individual resonance signals with the same sign, i.e. the individual resonance signals add constructively. In the case of a change in temperature and pressure, the frequencies of the individual resonance signals shift with different signs, and so these add destructively. The demodulated double resonance signal evaluated for the purpose of determining the magnetic field or magnetic field gradient is therefore only dependent on changes in the magnetic field, and influences of temperature and pressure are compensated.

In one embodiment, the signal generator unit comprises a first frequency mixer for forming the two frequency components of the first microwave signal with a phase offset of π with respect to one another, the said first frequency mixer being designed to mix the frequency of a first frequency-modulated signal and of a first oscillator signal, and the signal generator unit comprises a second frequency mixer for forming the two frequency components of the second frequency-modulated microwave signal with a phase offset of π with respect to one another, the said second signal generator unit being designed to mix the frequency of a second frequency-modulated signal and of a second oscillator signal.

Each of the first and the second oscillator signal is a signal at a constant oscillation frequency, which is mixed with the respective frequency-modulated signal. The first and the second frequency-modulated signal are generated by a respective signal generator of the signal generator unit and in each case have a respective carrier frequency and a modulation component. On account of frequency mixing, the first microwave signal contains frequency components with a phase offset of π with respect to one another. On account of frequency mixing, the second microwave signal accordingly also contains frequency components with a phase offset of π with respect to one another. The respective oscillation frequency and the carrier frequency of the frequency-modulated signal are chosen such that the two frequency components with a phase offset of π with respect to one another are each resonant with the transitions mₛ=0 ↔±1.

In some embodiments, the first and the second frequency-modulated signal have different carrier frequencies, and/or the first oscillator signal and the second oscillator signal have different oscillation frequencies. On account of the different magnetic field strengths in the first measurement region and in the second measurement region, the frequencies f₊ and f₋ in the two measurement regions, corresponding to the transitionsms=0 ↔±1, are typically different. Accordingly, it is generally necessary to choose the first carrier frequency and the second carrier frequency, and also the first oscillation frequency and the second oscillation frequency, to be different.

In order to form the first microwave signal in an alternative embodiment the signal generator unit comprises a first power adder for adding a first frequency-modulated microwave signal with two frequency components with a phase offset of π with respect to one another and a further first frequency-modulated microwave signal with two frequency components with a phase offset of π with respect to one another, and in order to form the second frequency-modulated microwave signal the signal generator unit comprises a second power adder for adding a second frequency-modulated microwave signal with two frequency components with a phase offset of π with respect to one another and a further second frequency-modulated microwave signal with two frequency components with a phase offset of π with respect to one another.

This embodiment is based on the same functional principle as the embodiment described further above. The use of the first power adder can lead to a difference between the power of the first frequency-modulated microwave signal and the power of the further first frequency-modulated microwave signal. The use of the second power adder can accordingly lead to a difference between the power of the second frequency-modulated microwave signal and the power of the further second frequency-modulated microwave signal. The respective frequency-modulated microwave signal in each case addresses one of the two magnetic field resonances in the first/second measurement region, while the further frequency-modulated microwave signal addresses the respective other magnetic field resonance in the first/second measurement region. The option of specifying a different power during the excitation of the individual resonances allows the difference in the scalar factors (see below) of the respective individual resonance spectra to be reduced during the evaluation of the respective demodulated fluorescence signal. This can increase the suppression of temperature and pressure changes in the demodulated double resonance signal.

In an advantageous embodiment, the signal generator unit is designed to set the power of the first frequency-modulated microwave signal and the power of the further first frequency-modulated microwave signal independently of one another, and the signal generator unit is designed to set the power of the second frequency-modulated microwave signal and the power of the further second frequency-modulated microwave signal independently of one another. It is advantageous if the power of the respective frequency-modulated microwave signal and the power of the respective further frequency-modulated microwave signal can not only be specified independently of one another but can also be set independently of one another. In this way, the difference in the scalar factors of the respective individual resonance spectra can be minimized during the evaluation of the respective demodulated fluorescence signal, and the suppression of temperature and pressure changes in the demodulated double resonance signal can be maximized. Independently setting the power can be implemented in different ways, as will be described in detail below.

In order to form the first frequency-modulated microwave signal in one embodiment the signal generator unit comprises a first frequency mixer for mixing the frequency of a frequency-modulated signal and of a first oscillator signal and in order to form the further first frequency-modulated microwave signal the said signal generator unit comprises a further first frequency mixer for mixing the frequency of the frequency-modulated signal and of a further first oscillator signal. In order to form the second frequency-modulated microwave signal the signal generator unit accordingly comprises a second frequency mixer for mixing the frequency of the frequency-modulated signal and of a second oscillator signal and in order to form the further second frequency-modulated microwave signal the said signal generator unit comprises a further second frequency mixer for mixing the frequency of the frequency-modulated signal and of a further second oscillator signal.

This embodiment provides for a signal generator which generates the frequency-modulated signal for all four frequency mixers. In this case, the frequency-modulated signal passes through a power splitter which divides the frequency-modulated signal among four power components which have a predetermined relationship to one another. A respective power component of the frequency-modulated signal is supplied to one of the four frequency mixers. As a rule, the four power components have the same magnitude, but this is not mandatory.

In a further embodiment, the signal generator comprises at least one programmable attenuator for settably attenuating a respective power component of the frequency-modulated signal supplied to a respective frequency mixer. In this case, the power component of the frequency-modulated signal supplied to a respective one of the four frequency mixers can be set on an individual basis with the aid of the programmable attenuator.

In one further embodiment, the signal generator unit comprises a first oscillator for generating the first oscillator signal, preferably with settable power, and a further first oscillator for generating the further first oscillator signal, preferably with settable power. Accordingly, the signal generator unit comprises a second oscillator for generating the second oscillator signal, preferably with settable power, and a further second oscillator for generating the further second oscillator signal, preferably with settable power. The power of the first frequency-modulated microwave signal and the power of the further first frequency-modulated microwave signal can be set independently of one another by virtue of the power of the first oscillator and the power of the further first oscillator, respectively, being set. A corresponding statement applies to the power of the second frequency-modulated microwave signal and the power of the further second frequency-modulated microwave signal.

In a further embodiment, the evaluation device comprises a first demodulator for forming a first demodulated double resonance signal from the detected fluorescence of the first measurement region and a second demodulator for forming a second demodulated double resonance signal from the detected fluorescence of the second measurement region. As described above, both magnetic resonances of the NV centers are excited and read simultaneously in the magnetic field gradiometer according to embodiments of the invention. The strength of the magnetic field in the first/second measurement region can be determined from the first/second demodulated double resonance signal.

In an embodiment, the two demodulators are designed as lock-in amplifiers in each case. In this embodiment, the demodulation of the double resonance signals is implemented with the aid of a lock-in amplifier. The respective lock-in amplifier typically comprises a frequency mixer, to which the double resonance signal and a reference signal are supplied. The signal resulting from frequency mixing passes through a low-pass filter, which is also a part of the lock-in amplifier. The demodulated double resonance signal at the output of the low-pass filter has a dispersive form and is linear around the resonant frequency.

According to one embodiment, the evaluation device is designed to determine a magnetic field-dependent resonance shift of a first magnetic field in the first measurement region on the basis of the first demodulated double resonance signal and to determine a magnetic field-dependent resonance shift of a second magnetic field in the second measurement region on the basis of the second demodulated double resonance signal. To determine the resonance shift, the gradient (“scaler factor” a) of the linear range of the demodulated double resonance signal is typically determined. To this end, the respective microwave field is initially radiated-in resonantly. Should the resonant frequency change on account of magnetic field, temperature or pressure changes, the detuning or the resonance shift Δ from the resonant frequency can be determined as follows on the basis of the demodulated double resonance signal v_{LIA}: Δ=v_{LIA}/α. Since resonance shifts on account of temperature or pressure changes add destructively in the two individual resonance signals (see above), the resonance shift of the double resonance signal v_{LIA} only depends on magnetic field changes in the respective measurement region, i.e. the following applies: ΔB=v_{LIA}/α.

A further aspect of the invention relates to a magnetic field gradiometer of the aforementioned type, wherein signal generator unit comprises a first power adder for forming a first microwave signal for the first microwave emitter by adding two first frequency-modulated microwave signals, wherein the signal generator unit comprises a second power adder for forming a second microwave signal for the second microwave emitter by adding two second frequency-modulated microwave signals, and wherein the evaluation device comprises a first power splitter for dividing the power of the detected fluorescence from the first measurement region among a first pair of demodulators and a second power splitter for dividing the power of the detected fluorescence from the second measurement region among a second pair of demodulators.

The magnetic field gradiometer according to the second aspect of the invention differs from the magnetic field gradiometer according to the first aspect of the invention in that the double resonance excitation is implemented using two different frequency bands that correspond to the two frequency-modulated microwave signals whose powers are added in the respective power adder. The information contained in the frequency bands in each case corresponds to a single resonance excitation and can be extracted by means of one of the two demodulators in each case. On the basis of the two demodulated single resonance signals v_{LIA+} and v_{LIA-}, the magnetic field-dependent resonance shift v_{LIA+}/a₊ and v_{LIA-}/α₋ _can be determined in the manner described above. As described above, the influences of temperature and pressure variations can be eliminated by subtraction when determining the respective magnetic field.

In one embodiment, the signal generator unit is designed to generate the first frequency-modulated microwave signals with different carrier frequencies in each case and to create the second frequency-modulated microwave signals with different carrier frequencies in each case. As described above, the two magnetic field resonances of the NV centers can be addressed independently of one another by way of the choice of different carrier frequencies.

In all cases described above, the simultaneous excitation and evaluation of the two magnetic field resonances allows magnetic field changes to be decoupled from changes in the temperature and pressure without limiting the bandwidth of the magnetic field gradiometer in the process. The methods described above differ in terms of their technical complexity and degree of temperature and pressure compensation.

The features mentioned above and those that are yet to be presented may be used in each case by themselves or as a plurality in any desired combinations. The embodiments shown and described should not be understood as an exhaustive list, but rather are of exemplary character.

In the following description of the drawings, identical reference signs are used for identical or corresponding components.

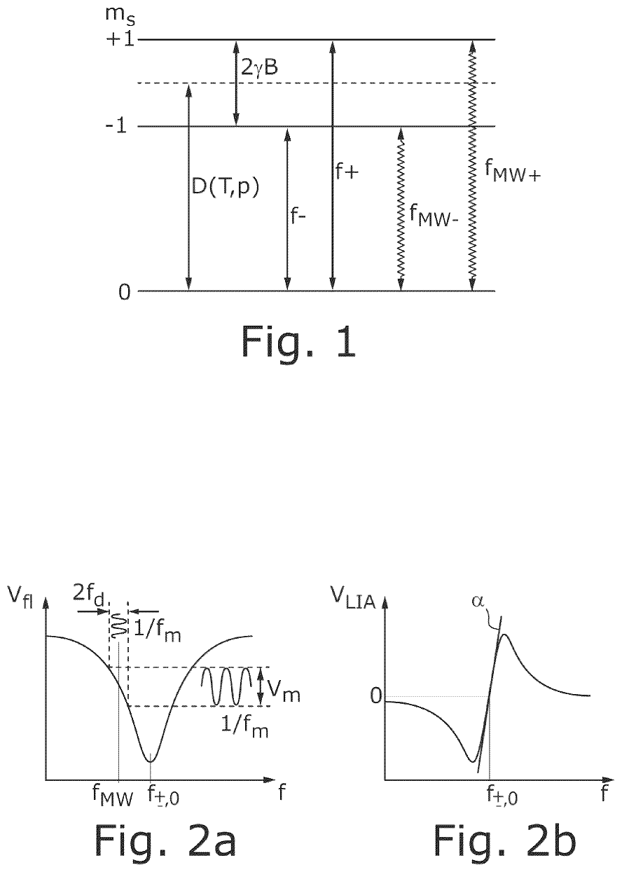

FIG. 1 shows a sketch of energy levels of a ground state of an NV center of a diamond crystal, present in the form of a triplet The respective three states of the triplet differ in their magnetic spin quantum number, mₛ=−1,0, +1. The mₛ=±1 states are higher energy due to the spin-spin interaction than the mₛ=0 state. Without magnetic field, the mₛ=±1 states are degenerate (if the hyperfine structure is neglected), thus have the same energy. In the presence of a magnetic field, the degeneracy of the mₛ=±1 states is lifted proportionally to the magnetic field due to the Zeeman effect. Thus there are two resonant frequencies f₊ and f₋, corresponding to the transitions between the mₛ=0 and the mₛ=+1 state or the mₛ=−1 state.

The resonant frequencies f_{±} depend on the magnetic field B, the temperature T and the pressure p at the location of the respective NV center. The following applies (cf. FIG. 1):

$${f}_{\pm } = D ( T , p ) \pm γ B .$$

Here, γ denotes the gyromagnetic ratio of the NV centers, and B denotes the projection of the magnetic field on the corresponding axis of the NV center.

As evident from the formula above, fluctuations in temperature T and pressure p can be separated from magnetic field changes if the two resonant frequencies f_{±} are known:

$${f}_{+} - {f}_{-} = 2 γ B .$$

As likewise evident from FIG. 1, two microwave fields with corresponding microwave frequencies f_{MW+}, f_{MW-} can be used to excite the two resonant frequencies f_{±}.

By radiating in excitation light in the green wavelength range, the NV centers can be pumped out of the ground state shown in FIG. 1 into the excited state, which is also present in the form of a triplet. The return into the ground state partially takes place with the emission of red fluorescence. The intensity of this fluorescence is dependent on the population distribution between the mₛ=−1,0, +1 states of the triplet ground state. This population distribution can be influenced by interaction with a resonant microwave field. In detail, in the case of a microwave field with frequencies f_{MW+} and f_{MW-}, corresponding to the frequencies f_{±,0} of the transitions between the mₛ=0 and the mₛ=+1 state or the mₛ=−1 state, there is a drop in the detected intensity of the fluorescence v_{FL}, as evident in FIG. 2a, which shows the intensity v_{FL} of the fluorescence as a function of frequency f. The intensity v_{FL} of the fluorescence has a minimum at the respective resonant frequency f_{±,0}.

The magnetic resonances are addressed by means of a frequency-modulated microwave field f_{MW} (t), which has the following form:

$${f}_{MW} ( t ) = {f}_{MW} + {f}_{d} cos ( 2 π {f}_{m} t ) ,$$

where f_{MW} denotes the carrier frequency, f_{d} denotes the modulation amplitude and fₘ denotes the modulation frequency. The intensity v_{FL} of the fluorescence is modulated accordingly with a modulation amplitude Vₘ and the modulation frequency fₘ.

FIG. 2b shows the signal v_{LIA} generated from the detected fluorescence by means of a demodulator in the form of a lock-in amplifier as a function of frequency f. As evident from FIG. 2b, the demodulated signal v_{LIA} has a dispersive form and is linear around the respective resonant frequency f_{±,0}. The gradient α of the linear region can be determined from the demodulated signal v_{LIA}. Should the resonant frequency change on account of magnetic field, temperature and/or pressure changes, the resonance shift (detuning) A from the resonant frequency f_{±,0} can be evaluated on the basis of the demodulated signal v_{LIA}. The following applies: Δ=v_{LIA}/α.

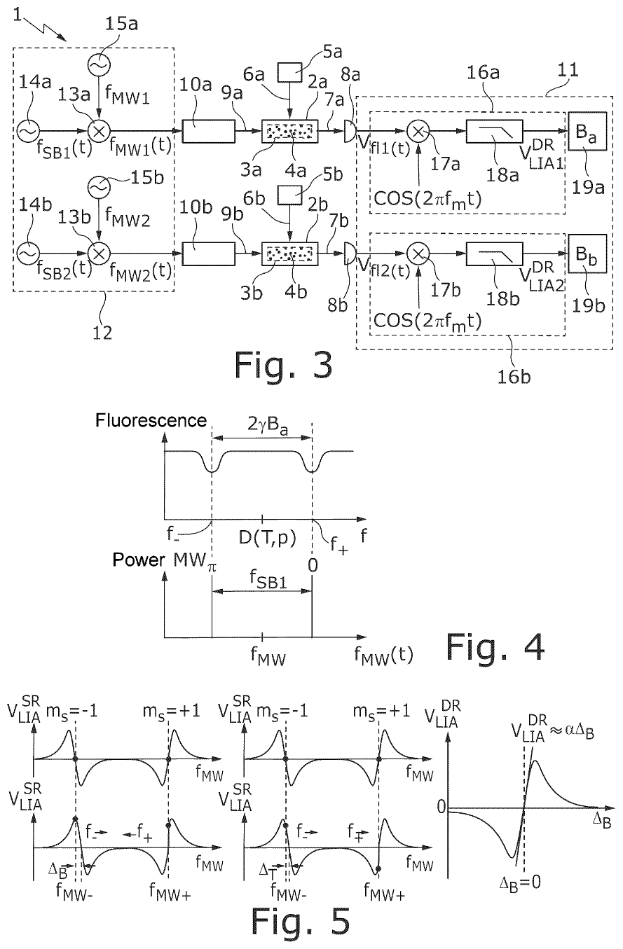

The above-described measurement principle can be used to simultaneously excite the two magnetic field resonances of an NV center. A magnetic field gradiometer 1 in which this is the case is described below in conjunction with FIG. 3.

The magnetic field gradiometer 1 comprises a first diamond crystal 2a and a second diamond crystal 2b, which each have a measurement region 3a, 3b in which the diamond crystal 2a, 2b is doped with NV centers 4a, 4b. The magnetic field gradiometer 1 also comprises two excitation light sources 5a, 5b, which each serve to emit excitation light 6a, 6b in the green wavelength range. In the event of NV centers 4a, 4b being excited in the respective measurement region 3a, 3b, fluorescence 7a, 7b is generated in the red wavelength range and detected by a respective detector 8a, 8b in the form of a photodiode.

In order to determine the strength of the magnetic field Bₐ, B_{b} in the respective measurement region 3a, 3b, a respective microwave field 9a, 9b generated by an associated microwave emitter 10a, 10b is applied to the respective diamond crystal 2a, 2b in addition to the irradiation with the excitation light 6a, 6b. The magnetic field gradiometer 1 comprises an evaluation device 11 for the determination of the strength of the respective magnetic field Bₐ, B_{b}. A signal generator unit 12 serves to generate a first microwave signal f_{MW1}(t) for the first microwave emitter 10a and a second microwave signal f_{MW2} (t) for the second microwave emitter 10b.

In order to form the first microwave signal f_{MW1}(t), the signal generator unit 12 comprises a first frequency mixer 13a designed to mix the frequency of a first frequency-modulated signal f_{SB1}(t) and of a first oscillator signal f_{MW1}. In order to generate the first frequency-modulated signal f_{SB1}(t), the signal generator unit 12 comprises a first signal generator 14a. In order to generate the first oscillator signal f_{MW1}, the signal generator unit 12 comprises a first oscillator 15a.

In order to form the second microwave signal f_{MW2} (t), the signal generator unit 12 comprises a second frequency mixer 13b designed to mix the frequency of a second frequency-modulated signal f_{SB2}(t) and of a second oscillator signal f_{MW2}. In order to generate the second frequency-modulated signal f_{SB2}(t), the signal generator unit 12 comprises a second signal generator 14b. In order to generate the second oscillator signal f_{MW2}, the signal generator unit 12 furthermore comprises a second oscillator 15b.

The first signal generator 14a is designed to generate the first frequency-modulated signal f_{SB1}(t) with a carrier frequency f_{SB1}, a modulation frequency fₘ₁ and a modulation amplitude f_{d1} in the form specified below:

$${f}_{SB 1} ( t ) = {f}_{SB 1} + {f}_{d 1} cos ( 2 π {f}_{m 1} t ) .$$

Accordingly, the second signal generator 14b is designed to generate the second frequency-modulated signal f_{SB2}(t) with a carrier frequency f_{SB2}, a modulation frequency fₘ₂ and a modulation amplitude f_{d2} in the form specified below:

$${f}_{SB 2} ( t ) = {f}_{SB 2} + {f}_{d 2} cos ( 2 π {f}_{m 2} t ) .$$

The first oscillator 15a generates the first oscillator signal f_{MW1} with a constant first oscillation frequency, which is denoted by f_{MW1} in order to simplify matters. Accordingly, the second oscillator 15b generates the second oscillator signal f_{MW2} with a constant second oscillation frequency, which is denoted by f_{MW2} in order to simplify matters.

As described above, the first frequency mixer 13a serves to form the first microwave signal f_{MW1}(t) by mixing the frequencies of the first frequency-modulated signal f_{SB1}(t) and of the first oscillator signal f_{MW1}. Post frequency mixing in the first frequency mixer 13a, the first microwave signal f_{MW1}(t) has the following frequency components:

$${f}_{MW 1} + {f}_{SB 1} + {f}_{d 1} cos ( 2 π {f}_{m 1} t )$$

$$and$$

$${f}_{MW 1} - {f}_{SB 1} + {f}_{d 1} cos ( 2 π {f}_{m 1} t + π )$$

Frequency mixing thus results in a phase difference of π or 180° between the two frequency components f_{d1} cos (2πfₘ₁t) and f_{d1} cos (2πfₘ₁t+π) of the first microwave signal f_{MW1}(t).

The aforementioned applies accordingly to the second microwave signal f_{MW2}(t), which is generated by the second frequency mixer 13b by mixing the frequency of the second frequency-modulated signal f_{SB2}(t) and of the second oscillator signal f_{MW2}. Therefore, the second microwave signal f_{MW2}(t) likewise has two frequency components f_{d2} cos (2πfₘ₂t) and f_{d2} cos (2πfₘ₂t+π), which have a phase difference of π or 180° with respect to one another.

The carrier frequency f_{SB1} of the first frequency-modulated signal f_{SB1}(t) and the oscillator frequency f_{MW1} of the first oscillator signal f_{MW1} are chosen such that, given a field strength of the magnetic field Bₐ in the first measurement region 3a, the two frequency components phase-shifted by π correspond to the two resonant frequencies f₊, f₋ of the transitions between the mₛ=0 and the mₛ=+1 state or the mₛ=−1 state, as illustrated in FIG. 4. Accordingly, the carrier frequency f_{SB2} of the second frequency-modulated signal f_{SB2}(t) and the oscillator frequency f_{MW2} of the second oscillator signal f_{MW2} are chosen such that the two resonant frequencies f₊, f₋ of the transitions between the mₛ=0 and the mₛ=+1 state or the mₛ=−1 state of the NV centers 4b in the second measurement region 3b are addressed.

In the case of the magnetic field gradiometer 1 from FIG. 3, the magnetic field Bₐ is intended to be measured within the first measurement region 3a. The magnetic field B_{b} at the location of the second measurement region 3b is used to measure the ambient magnetic field. Ambient magnetic field noise can be suppressed by forming the magnetic field gradient Bₐ-B_{b}, i.e. the difference between the first magnetic field Bₐ in the first measurement region 3a and the second magnetic field B_{b} in the second measurement region 3b. On account of the different field strengths of the magnetic fields Bₐ, B_{b} in the respective measurement regions 3a, 3b, it is typically necessary for the first and the second frequency-modulated signal f_{SB1}(t), f_{SB2}(t) to have different carrier frequencies f_{SB1}, f_{SB2} or for the first oscillator signal f_{MW1} and the second oscillator signal f_{MW2} to have different oscillation frequencies f_{MW1}, f_{MW2}.

As is evident from FIG. 2, the evaluation device 11 comprises a first demodulator 16a for forming a first demodulated double resonance signal v_{LIA}^{DR} from the fluorescence detected by means of the first detector 8a or from a corresponding fluorescence signal v_{FL1} (t) from the first measurement region 3a. Accordingly, the evaluation device 11 also comprises a second demodulator 16b for forming a second demodulated double resonance signal v_{LIA2}^{DR} from the fluorescence detected by means of the second detector 8b or from the corresponding fluorescence signal v_{FL2} (t) from the second measurement region 3b. The two demodulators 16a, 16b are designed as lock-in amplifiers and each comprise a frequency mixer 17a, 17b and a low-pass filter 18a, 18b. The first frequency mixer 17a is supplied a reference signal corresponding to the reference component f_{d1} cos (2πfₘ₁t) of the first microwave signal f_{MW1}(t). Accordingly, the second frequency mixer 17b is supplied a reference signal corresponding to the reference component f_{d2} cos (2πfₘ₂t) of the second microwave signal f_{MW2}(t). The respective first and second double resonance signals v_{LIA}^{DR} and v_{LIA2}^{DR}, respectively, have the dispersive form known from FIG. 2b.

FIG. 5 serves to illustrate the influence of changes in the magnetic field, the temperature and the pressure on a demodulated double resonance signal v_{LIA}^{DR} depicted to the right in FIG. 5, which signal for example could be the first or the second demodulated double resonance signal v_{LIA1}^{DR} or v_{LIA2}^{DR} from FIG. 3. In order to understand the influence of the change in the aforementioned quantities on the demodulated double resonance signal v_{LIA}^{DR}, FIG. 5 depicts the respective demodulated single resonance signals v_{LIA}^{SR} to the left and in the center. The relative modulation phase of π or 180° between the two frequency components of the microwave field results in a vertical reflection of the single resonance signals v_{LIA}^{SR} of the two magnetic resonances of the mₛ=+1 state or the mₛ=−1 state.

As evident in FIG. 5, bottom left, a resonance shift Δ_{B} that can be traced back to a magnetic field change leads to a shift in the single resonance signals v_{LIA}^{SR} which brings about constructive addition in the double resonance signal (cf. the points in FIG. 5, bottom left). Resonance shifts Δ_{T} (or Δₚ, not shown) that can be traced back to a change in temperature or pressure, by contrast, lead to a destructive addition of the single resonance signals v_{LIA}^{SR} (cf. the points in FIG. 5, bottom center). As depicted in FIG. 5, right, the demodulated double resonance signal v_{LIA}^{DR} therefore only depends on the magnetic field-related resonance shift Δ_{B} of the respective magnetic field Bₐ, B_{b} in the first measurement region 3a or in the second measurement region 3b. As evident in FIG. 5, right, the demodulated double resonance signal v_{LIA}^{DR} is linear in the region of the magnetic resonance around Δ_{B}. Accordingly, the magnetic field-dependent resonance shift Δ_{B} can be determined as follows on the basis of the demodulated double resonance signal v_{LIA}^{DR} while taking account of the gradient α: Δ_{B}=v_{LIA}^{DR}.

The considerations above apply both to the first demodulated double resonance signal v_{LIA1}^{DR} and to the second demodulated double resonance signal v_{LIA2}^{DR} of the magnetic field gradiometer 1 depicted in FIG. 3. The considerations below relate to the first double resonance signal v_{LIA1}^{DR} and apply accordingly to the second double resonance signal v_{LIA2}^{DR}.

The following procedure is implemented in the evaluation device 11 in order to determine the first magnetic field Bₐ: In a calibration step, a single resonance spectrum of the two magnetic resonances (cf. FIG. 2a and FIG. 4, respectively) is recorded in order to determine the resonant frequencies f_{+,0} and f_{-,0} at the time of calibration. In a subsequent step, the first demodulated double resonance signal v_{LIA}^{DR} is recorded during the calibration in the manner described above, and the scalar factor α or the gradient at Δ_{B}=0 is determined. Subsequently, the carrier frequency f_{SB1} of the first frequency-modulated signal f_{SB1}(t) and the oscillator frequency f_{MW1} of the first oscillator signal f_{MW1} are chosen or fixedly set such that, for the field strength of the magnetic field Bₐ in the first measurement region 3a present during the calibration, the two frequency components phase-shifted by π correspond to the two resonant frequencies f_{+,0}, f_{-,0} of the transitions between the mₛ=0 and the mₛ=+1 state or the mₛ=−1 state (cf. also FIG. 4).

Following the calibration, there is a continuous determination of the first magnetic field Bₐ by way of the following equation:

$$2 γ {B}_{a} = {f}_{+ , 0} - {f}_{- , 0} + 2 {V}_{LIA 1}^{DR} / α$$

The second magnetic field B_{b} is determined analogously. In order to calculate the respective magnetic field Bₐ, B_{b} from the first or from the second demodulated double residence signal v_{LIA1}^{DR} Or v_{LIA2}^{DR}, the evaluation device 11 comprises a respective calculation logic 19a, 19b, designed in the form of suitable hardware and/or software.

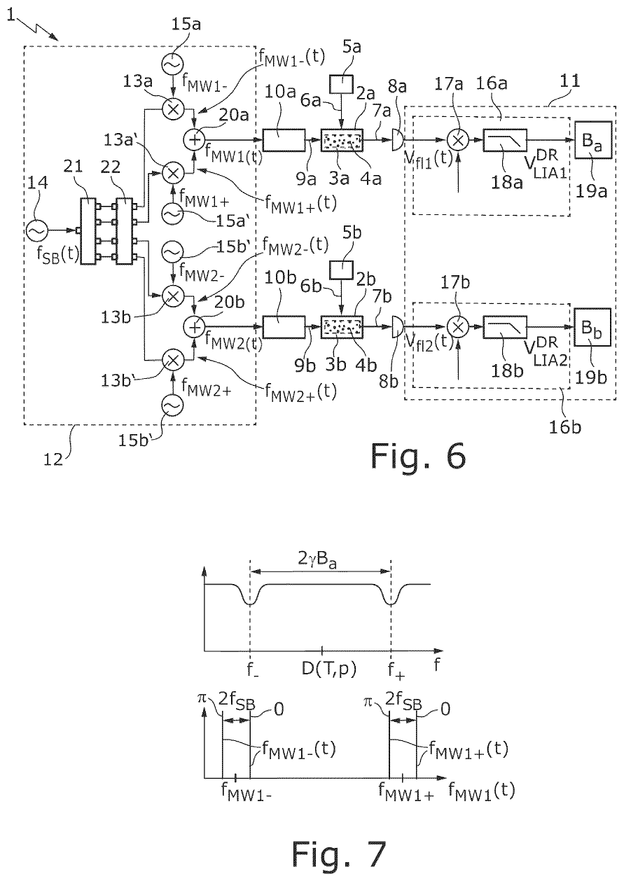

FIG. 6 shows a magnetic field gradiometer 1 which is based on the same measurement principle as the magnetic field gradiometer 1 shown in FIG. 3. The magnetic field gradiometer 1 shown in FIG. 6 substantially differs from the magnetic field gradiometer shown in FIG. 3 in terms of the design of the signal generator unit 12 which serves to individually set the power of the frequency bands that address the respective magnetic resonances. In order to form the first microwave signal f_{MW1}(t) the signal generator unit 12 comprises a first power adder 20a for adding a first frequency-modulated microwave signal f_{MW1-}(t) with two frequency components with a phase offset of π with respect to one another and a further first frequency-modulated microwave signal f_{MW1+}(t) with two frequency components with a phase offset of π with respect to one another. In order to form the second frequency-modulated microwave signal f_{MW2}(t) the signal generator unit 12 also comprises a second power adder 20b for adding a second frequency-modulated microwave signal f_{MW2-}(t) with two frequency components with a phase offset of π with respect to one another and a further second frequency-modulated microwave signal f_{MW2+}(t) with two frequency components with a phase offset of π with respect to one another.

In order to form the first frequency-modulated microwave signal f_{MW1-}(t), the signal generator unit 12 comprises a first frequency mixer 13a designed to mix the frequency of a frequency-modulated signal f_{SB} (t) and of a first oscillator signal f_{MW1-}. In order to form the further first frequency-modulated microwave signal f_{MW1}(t), the signal generator unit 12 accordingly comprises a further first frequency mixer 13a′ designed to mix the frequency of the frequency-modulated signal f_{SB} (t) and of a further first oscillator signal f_{MW1+}.

In order to form the second frequency-modulated microwave signal f_{MW2-}(t), the signal generator unit 12 moreover comprises a second frequency mixer 13b designed to mix the frequency of the frequency-modulated signal f_{SB}(t) and of a second oscillator signal f_{MW1-}. Furthermore, in order to form the further second frequency-modulated microwave signal f_{MW2+}(t), the signal generator unit 12 comprises a further second frequency mixer 13b′ which serves to mix the frequency of the frequency-modulated signal f_{SB}(t) and of a further second oscillator signal f_{MW2-}.

The frequency-modulated signal f_{SB}(t) is created in a signal generator 14 of the signal generator unit 12. The first oscillator signal f_{MW1-} and the further first oscillator signal f_{MW1+} are generated in a first oscillator 15a and in a further first oscillator 15a′, respectively. Accordingly, the second oscillator signal f_{MW2-} and the further second oscillator signal f_{MW2+} are generated in a second oscillator 15b and in a further second oscillator 15b′, respectively.

The signal generator unit 12 is designed to set the power of the first frequency-modulated microwave signal f_{MW1-}(t) and of the further first frequency-modulated microwave signal f_{MW1+}(t) independently of one another. Moreover, the signal generator unit 12 is designed to set the power of the second frequency-modulated microwave signal f_{MW2-}(t) and of the further second frequency-modulated microwave signal f_{MW2+}(t) independently of one another.

To this end, the power of the frequency-modulated signal f_{SB}(t) is initially divided into four power components of equal size at a first power splitter 21. Subsequently, the power component of the frequency-modulated signal f_{SB}(t) supplied to a respective frequency mixer 13a, 13a′, 13b, 13b′ is set on an individual basis with the aid of a programmable attenuator 22. In an alternative to that or in addition, it is possible that the four oscillators 15a, 15a′, 15b, 15b′ are designed to generate the corresponding oscillator signal f_{MW1-}, f_{MW1+}, f_{MW2-}, f_{MW2+} within each case an individually settable power.

In a manner analogous to the illustration of FIG. 4, FIG. 7 shows the frequency components of the first microwave signal f_{MW1}(t) generated by the signal generator 12 from FIG. 6. As evident from FIG. 7, the first microwave signal f_{MW1}(t) contains two pairs within each case two frequency components phase-shifted by π with respect to one another. As a result of the possibility of setting the power for the respective frequency bands or for the first frequency-modulated microwave signal f_{MW1-}(t) and for the second frequency-modulated microwave signal f_{MW1+}(t) on an individual basis, the difference in the scalar factors α of the respective single resonance spectra can be minimized, and hence the suppression of temperature- and pressure changes in the double resonance signal v_{LIA1}^{DR} can be maximized. It is understood that the considerations above also apply analogously to the second microwave signal f_{MW2}(t).

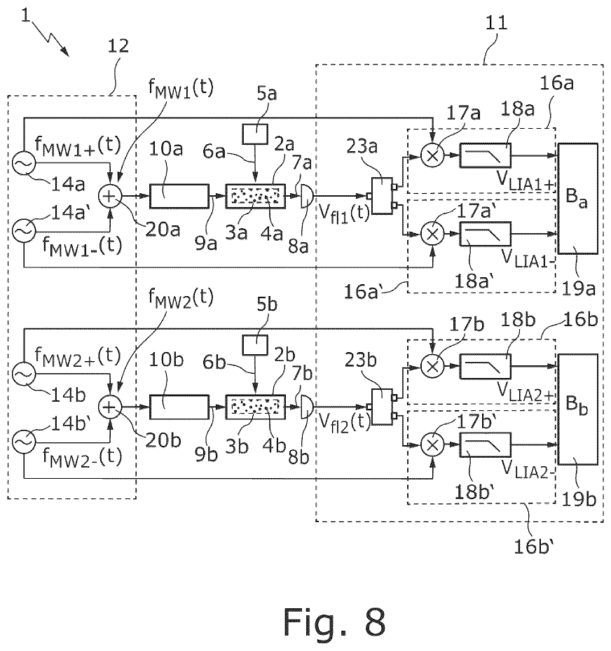

FIG. 8 shows a magnetic field gradiometer 1 which differs from the magnetic field gradiometers shown in FIG. 3 and FIG. 6 in terms of the structure of the signal generator unit 12 and the evaluation device 11. In the case of the magnetic field gradiometer 1 shown in FIG. 8, the signal generator unit 12 comprises a first power adder 20a for forming a first microwave signal f_{MW1}(t) for the first microwave emitter 10a by adding two first frequency-modulated microwave signals f_{MW1+}(t), f_{MW1-}(t). Accordingly, the signal generator unit 12 comprises a second power adder 20b for forming a second microwave signal f_{MW2}(t) for the second microwave emitter 10b by adding two second frequency-modulated microwave signals f_{MW2+}(t), f_{MW2-}(t). The first frequency-modulated microwave signals f_{MW1+}(t), f_{MW1-}(t) are generated in a respective first and further first signal generator 14a, 14a′. Accordingly, the second frequency-modulated microwave signals f_{MW2+}(t), f_{MW2-}(t) are generated in a respective second and further second signal generator 14b, 14b′.

The following applies to the first frequency-modulated microwave signals f_{MW1+}(t), f_{MW1-}(t):

$${f}_{MW 1 \pm } ( t ) = {f}_{MW 1 \pm } + {f}_{d} cos ( 2 π {f}_{m 1 \pm } t ) ,$$

where f_{MW1±} denotes the respective carrier frequency, f_{m1±} denotes the respective modulation frequency and fa denotes the modulation amplitude. The carrier frequencies f_{m1±} of the two first frequency-modulated microwave signals f_{MW1+}(t), f_{MW1-}(t) differ from one another in order to each excite one of the two magnetic resonances of the NV centers 4a in the first measurement region 3a.

The fluorescence signal v_{fl1}(t) which is detected by the first detector 8a of the magnetic field gradiometer 1 therefore contains information about the magnetic resonances in two different frequency bands centered around f_{m1±}. The evaluation device 11 comprises a first power splitter 23a for dividing the power of the detected fluorescence signal v_{fl1} (t) from the first measurement region 3a among a first pair of demodulators 16a, 16a′. Accordingly, a second power splitter 23b serves to divide the power of the detected fluorescence signal v_{fl2} (t) from the second measurement region 3b among a second pair of demodulators 16b, 16b′. A demodulated single resonance signal v_{LIA1+}, v_{LIA1-}, v_{LIA2+}, v_{LIA2-}, which can be evaluated in the manner described above in the context of FIG. 2b, is generated in a respective demodulator 16a, 16a′, 16b, 16b′.

The following relationship arises for the first magnetic field Bₐ in the first measurement region 3a:

$$2 γ {B}_{a} = ( {f}_{+ , 0} + \frac{{V}_{LIA 1 +}}{{α}_{1 +}} ) - ( {f}_{- , 0} + \frac{{V}_{LIA 1 -}}{{α}_{1 -}} ) ,$$

where α₁₊ and α₁₋ denote the gradient of the respective single resonance signal v_{LIA1+}, v_{LIA1-} at Δ_{B}=0. With the aid of the formula specified above, the first magnetic field Bₐ is determined from the two demodulated single resonance signals v_{LIA1+}, v_{LIA1-} in a first calculation logic 19a. A corresponding statement applies to the determination of the second magnetic field B_{b} in the second measurement region 3b on the basis of the two second demodulated single resonance signals v_{LIA2+}, v_{LIA2-} in a second calculation logic 19b.

In summary, the respective magnetic field Bₐ, B_{b} or magnetic field gradient Bₐ-B_{B} can be determined in a manner decoupled from temperature- and pressure changes by using the above-described magnetic field gradiometer 1, without this limiting the bandwidth of the magnetic field gradiometer 1. Hence, the full dynamic range of the magnetic field gradiometer 1 is usable. As a rule, it is also not necessary to heat or cool the respective diamond crystals 3a, 3b in order to stabilize the temperature thereof.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

The invention claimed is:

1. A magnetic field gradiometer for determining a magnetic field gradient, the magnetic field gradiometer comprising:
at least one excitation light source for emitting excitation light,
two spatially spaced-apart measurement regions for magnetic field measurement, the two measurement regions comprising color centers in a diamond, which emit fluorescence upon excitation by the excitation light,
a first detector for detecting the fluorescence from a first measurement region of the two measurement regions,
a second detector for detecting the fluorescence from a second measurement region of the two measurement regions,
a first microwave emitter for applying a first microwave field to the first measurement region,
a second microwave emitter for applying a second microwave field to the second measurement region,
an evaluation device configured to determine the magnetic field gradient based on the detected fluorescence from the first measurement region and the detected fluorescence from the second measurement region, and
a signal generator unit configured to generate a first microwave signal for the first microwave emitter, the first microwave signal comprising at least two frequency components with a phase offset of π with respect to one another, and a second microwave signal for the second microwave emitter, the second microwave signal comprising at least two frequency components with a phase offset of π with respect to one another.

2. The magnetic field gradiometer as claimed in claim 1, wherein the signal generator unit comprises a first frequency mixer for forming the two frequency components of the first microwave signal) with the phase offset of π with respect to one another, the first frequency mixer being configured to mix a frequency of a first frequency-modulated signal) and a frequency of a first oscillator signal, and wherein the signal generator unit comprises a second frequency mixer for forming the two frequency components of the second microwave signal) with the phase offset of π with respect to one another, the second signal generator unit being configured to mix a frequency of a second frequency-modulated signal) and a frequency of a second oscillator signal.

3. The magnetic field gradiometer as claimed in claim 2, wherein the first frequency-modulated signal and the second frequency-modulated signal have different carrier frequencies, and/or wherein the first oscillator signal and the second oscillator signal have different oscillation frequencies.

4. The magnetic field gradiometer as claimed in claim 1, wherein, in order to form the first microwave signal,) the signal generator unit comprises a first power adder for adding a first frequency-modulated microwave signal) with two frequency components with the phase offset of π with respect to one another and a further first frequency-modulated microwave signal) with two frequency components with the phase offset of π with respect to one another, and
wherein, in order to form the second microwave signal,) the signal generator unit comprises a second power adder for adding a second frequency-modulated microwave signal) with two frequency components with the phase offset of π with respect to one another and a further second frequency-modulated microwave signal) with two frequency components with the phase offset of π with respect to one another.

5. The magnetic field gradiometer as claimed in claim 4, wherein the signal generator unit is configured to set a power of the first frequency-modulated microwave signal) and a power of the further first frequency-modulated microwave signal) independently of one another, and to set a power of the second frequency-modulated microwave signal) and a power of the further second frequency-modulated microwave signal) independently of one another.

6. The magnetic field gradiometer as claimed in claim 4, wherein, in order to form the first frequency-modulated microwave signal,) the signal generator unit comprises a first frequency mixer for mixing a frequency of a frequency-modulated signal) and of a first oscillator signal, and in order to form the further first frequency-modulated microwave signal,) the signal generator unit comprises a further first frequency mixer for mixing a frequency of the frequency-modulated signal) and a frequency of a further first oscillator signal.

7. The magnetic field gradiometer as claimed in claim 6, wherein the signal generator comprises at least one programmable attenuator for settably attenuating a respective power component of the frequency-modulated signal) supplied to a respective one of the first frequency mixer and the further first frequency mixer.

8. The magnetic field gradiometer as claimed in claim 6, wherein the signal generator unit comprises a first oscillator for generating the first oscillator signal, and a further first oscillator for generating the further first oscillator signal.

9. The magnetic field gradiometer as claimed in claim 1, wherein the evaluation device comprises a first demodulator for forming a first demodulated double resonance signal from the detected fluorescence) of the first measurement region, and a second demodulator for forming a second demodulated double resonance signal from the detected fluorescence) of the second measurement region.

10. The magnetic field gradiometer as claimed in claim 9, wherein the first demodulator and the second demodulator are configured as lock-in amplifiers.

11. The magnetic field gradiometer as claimed in claim 9, wherein the evaluation device is configured to determine a first magnetic field-dependent resonance shift of a first magnetic field in the first measurement region based on the first demodulated double resonance signal, and to determine a second magnetic field-dependent resonance shift of a second magnetic field in the second measurement region based on the second demodulated double resonance signal.

12. The magnetic field gradiometer as claimed in claim 1,
wherein
the signal generator unit comprises a first power adder for forming the first microwave signal) for the first microwave emitter by adding two first frequency-modulated microwave signals,
the signal generator unit comprises a second power adder for forming the second microwave signal) for the second microwave emitter by adding two second frequency-modulated microwave signals, and
the evaluation device comprises a first power splitter for dividing a power of the detected fluorescence) from the first measurement region among a first pair of demodulators, and a second power splitter for dividing a power of the detected fluorescence) from the second measurement region among a second pair of demodulators.

13. The magnetic field gradiometer as claimed in claim 12, wherein the signal generator unit is configured to generate the two first frequency-modulated microwave signals with different carrier frequencies, and to generate the two second frequency-modulated microwave signals with different carrier frequencies.
